(19) United States
(12) Patent Application Publication
(10) Pub. No.: US 2010/0006847 A1
(43) Pub. Date: Jan. 14, 2010

(54) SEMICONDUCTOR DEVICE, DISPLAY APPARATUS, PHOTO-ELECTRICAL APPARATUS, AND METHOD FOR FABRICATING THE SAME

(75) Inventors: Chin-Wei Hu, Hsinchu County (TW); Kun-Chih Lin, Miaoli County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: AU OPTRONICS CORPORATION, Hsinchu (TW)

(21) Appl. No.: 12/241,071

(22) Filed: Sep. 30, 2008

(30) Foreign Application Priority Data
Jul. 10, 2008 (TW) 97126183

(51) Int. Cl. H01L 21/8238; H01L 29/786

(52) U.S. Cl. 257/66; 438/154; 257/E21.632; 257/E29.273

(57) ABSTRACT

A semiconductor device and the method for fabricating the same are disclosed. The fabrication method includes forming a PMOS device and an NMOS device on a substrate, wherein the PMOS device includes a first poly-silicon island, a gate dielectric layer covering the first poly-silicon island, and a first gate on the gate dielectric layer. The method of fabrication the PMOS device includes performing a P-type ion implantation process on the first poly-silicon island to form a plurality of P-type heavily doped regions and a plurality of P-type lightly doped regions. The length of the channel region is substantially less than 3 micron, and the length of at least one of the P-type lightly doped regions substantially is 10%-80% of the length of the channel region. The P-type lightly doped regions are used to improve the short channel effect of the PMOS device.

### CROSS-REFERENCE TO RELATED APPLICATION

This application claims the priority benefit of Taiwan application serial no. 97126183, filed on Jul. 10, 2008. The entirety of the above-mentioned patent application is hereby incorporated by reference herein and made a part of specification.

### BACKGROUND OF THE INVENTION

1. Field of the Invention

The present invention generally relates to a semiconductor device, a display apparatus and a photo-electrical apparatus, and a method for fabricating the same, and more particularly, to a complementary metal oxide semiconductor (CMOS) device and a method of fabrication the CMOS device.

2. Description of Related Art

The increasing progresses of the display technology bring great conveniences with the people's daily life, wherein the flat panel display (FPD) has played the major role on the display market due to the inherent light-thin feature thereof.

In general, semiconductor devices used within a display area of an FPD can be categorized into low temperature poly-silicon metal oxide semiconductor device (LTPS MOS device) and amorphous silicon thin film transistor (a-Si TFT). Since the electron mobility in an LTPS MOS can be over 200 cm²/V-sec, the LTPS MOS device can be designed in smaller size, which further promotes the aperture ratio (AR) of the FPD and reduces the power consumption.

However, the length of a channel region in an LTPS MOS device gets smaller with a reduced size thereof. Therefore, if the LTPS MOS device is driven with the regular design parameters, the energy of electrons at the boundary between the channel region and the drain becomes higher, which may worsen current leaking, i.e., trigger a short channel effect, so that the electric performance of the LTPS MOS device further gets deteriorated.

FIG. 1 is a locally sectional diagram of a conventional LTPS MOS device. Referring to FIG. 1, the LTPS MOS device 100 includes a PMOS device 110 and an NMOS device 120, wherein the PMOS device 110 includes a first poly-silicon island 112, a gate dielectric layer 114 covering the first poly-silicon island 112, and a first gate 116 located on the gate dielectric layer 114. The NMOS device 120 includes a second poly-silicon island 122 and a second gate 126 located on the gate dielectric layer 114.

The PMOS device 110 has a structure only with a plurality of P-type heavily doped regions 112a as shown in FIG. 1. The second poly-silicon island 122 of the NMOS device 120 has a plurality of N-type heavily doped regions 122a and a plurality of N-type lightly doped drains LDD_{N}′. Usually, the N-type lightly doped drains LDD_{N}′ are used to prevent the short channel effect of the NMOS device 120; but skilled artisans pay less attention to the short channel effect problem in the PMOS device 110 and the resulted performance deterioration by the short channel effect, on the contrary, skilled artisans even think that a smaller channel in the PMOS device 110 is useless to improve the performance thereof and the short channel effect problem can be solved by other schemes. According to a conventional view, the performance of the PMOS device 110 should be improved by, for example, making the crystal grain size of the first poly-silicon island 112 in the PMOS device 110 close to that of the second poly-silicon island 122 in the NMOS device 120.

### SUMMARY OF THE INVENTION

Accordingly, the present invention is directed to a semiconductor device including PMOS devices and NMOS devices and a fabrication method thereof, wherein both the PMOS device and the NMOS device have a lightly doped drain region.

The present invention is also directed to a method of fabrication a display apparatus having the above-mentioned semiconductor devices.

The present invention is also directed to a method of fabrication a photo-eletrical apparatus having the above-mentioned semiconductor devices.

The present invention provides a method for fabricating a semiconductor device, the method includes forming a PMOS device and an NMOS device on a substrate, wherein the PMOS device includes a first poly-silicon island, a gate dielectric layer covering the first poly-silicon island and a first gate on the gate dielectric layer, and the first gate is located over the first poly-silicon island. The PMOS device is fabricated as following. First, a first patterned photoresist layer is formed on the gate dielectric layer and the first gate, wherein the first patterned photoresist layer has a plurality of first openings. Next, a P-type ion implant process on the first poly-silicon island is performed by using the first patterned photoresist layer as a mask to form a plurality of P-type heavily doped regions in the first poly-silicon island under the first openings. Then, parts of the first patterned photoresist layer are removed to form a second patterned photoresist layer having a plurality of second openings, wherein the size of each second opening is substantially greater than the size of each first opening. After that, a P-type ion implant process on the first poly-silicon island is performed by using the first gate and the second patterned photoresist layer as a mask to form a plurality of P-type lightly doped regions in the first poly-silicon island under the second openings, wherein the part of the first poly-silicon island under the first gate serves as a channel region located between the P-type heavily doped regions and between the P-type lightly doped regions, the length of the channel region is substantially less than 3 micron, and the length of at least one of the P-type lightly doped regions substantially is 10%-80% of the length of the channel region.

The present invention also provides a method of fabrication a display apparatus, wherein the method includes the method of fabrication the above-mentioned semiconductor devices.

The present invention also provides a method of fabrication a photo-eletrical apparatus, wherein the method includes the method of fabrication the above-mentioned semiconductor devices.

The present invention further provides a semiconductor device, which includes a substrate, at least a PMOS device and at least an NMOS device. The PMOS device is disposed on the substrate, and the PMOS device includes a first poly-silicon island, a gate dielectric layer covering the first poly-silicon island, and a first gate located on the gate dielectric layer. The first gate is located on the first poly-silicon island, and the first poly-silicon island has a plurality of P-type heavily doped regions, a plurality of P-type lightly doped regions and a channel region between the P-type lightly doped regions, wherein the length of the channel region is substantially less than 3 micron and the length of at least one of the P-type lightly doped regions substantially is 10%-80% of the length of the channel region. The NMOS device is disposed on the substrate, and the NMOS device includes a second poly-silicon island, a gate dielectric layer covering the second poly-silicon island, and a second gate on the gate dielectric layer. The second gate is located on the second poly-silicon island, and the second poly-silicon island has a plurality of N-type heavily doped regions, a plurality of N-type lightly-doped regions, and a channel region between the N-type lightly-doped regions.

The present invention also provides a display apparatus including the above-mentioned semiconductor devices.

The present invention also provides a photo-electrical apparatus including the above-mentioned semiconductor devices.

The invented semiconductor device includes a PMOS device and an NMOS device, wherein both the PMOS device and the NMOS device have a lightly doped drain (P-type lightly doped drain or N-type lightly doped drain). Therefore, the short channel effects of the PMOS device and the NMOS device can be reduced. In particular, the P-type lightly doped drain can be fabricated without additional cost.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a locally sectional diagram of a conventional LTPS MOS device.

FIG. 2A is a locally sectional diagram of a semiconductor device according to an embodiment of the present invention.

FIG. 2B is a flowchart of a method for fabricating a PMOS device according to an embodiment of the present invention.

FIGS. 3A-3E are sectional diagrams of a PMOS device in association with a fabricating process flow according to an embodiment of the present invention.

FIGS. 3F and 3G are curve graphs of drain current vs. gate voltage of a conventional PMOS device under different conditions.

FIGS. 3H and 3I are curve graphs of drain current vs. gate voltage of a PMOS device under different operation voltages according to an embodiment of the present invention.

FIG. 3J is a diagram showing relationships between the threshold voltage and the length of lightly doped region respectively corresponding to a conventional PMOS device and an invented PMOS device provided by an embodiment of the present invention.

FIG. 4 is a locally sectional diagram of an NMOS device according to an embodiment of the present invention.

FIG. 4A is a locally sectional diagram of an N-doped region according to an embodiment of the present invention.

FIG. 4B and FIG. 4B′ are two locally sectional diagrams of an N-doped region according to another embodiment of the present invention.

FIG. 4C is a locally sectional diagram of an N-doped region according to yet another embodiment of the present invention.

FIGS. 5A-5E are sectional diagrams of a semiconductor device in association with a fabricating process flow according to an embodiment of the present invention.

FIG. 6A is a diagram of a display apparatus according to an embodiment of the present invention.

FIG. 6B is a diagram of a photo-electrical apparatus according to an embodiment of the present invention.

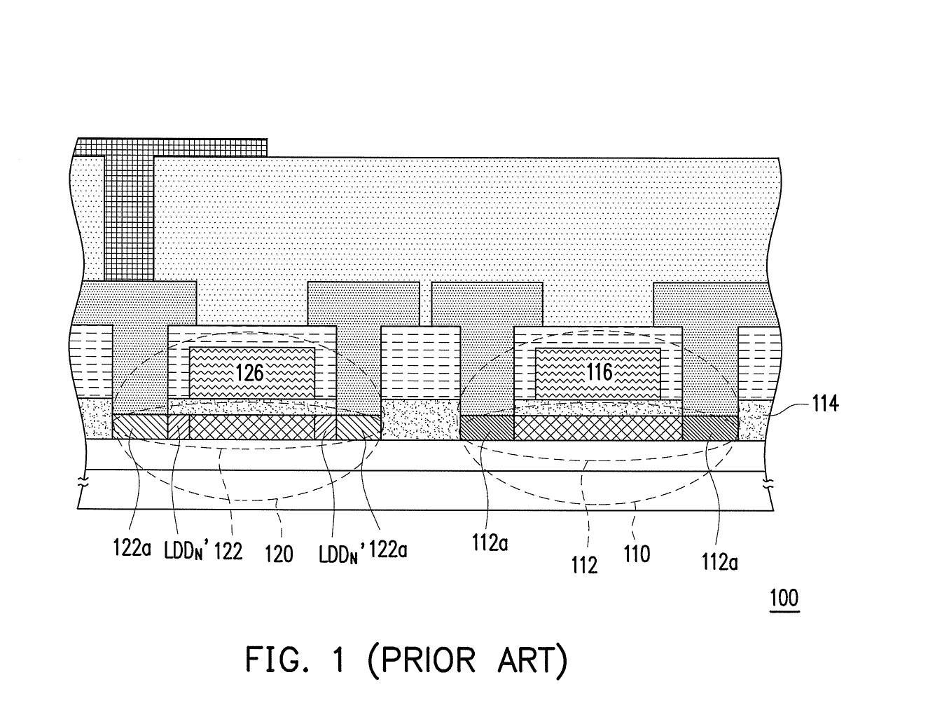

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

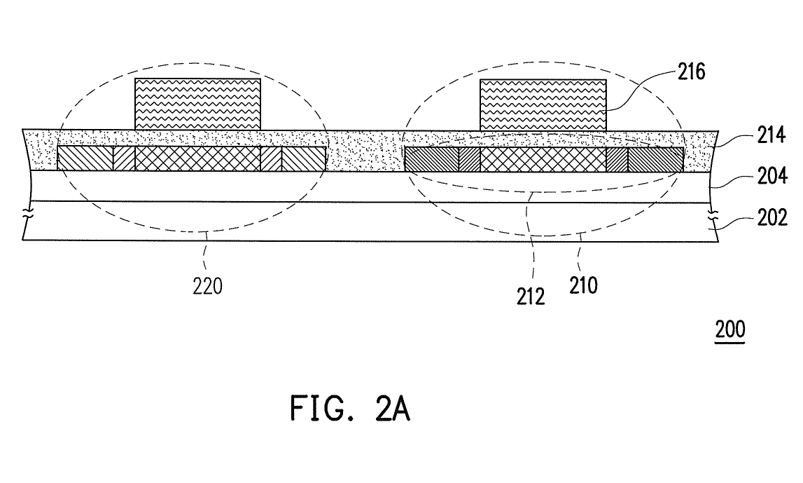

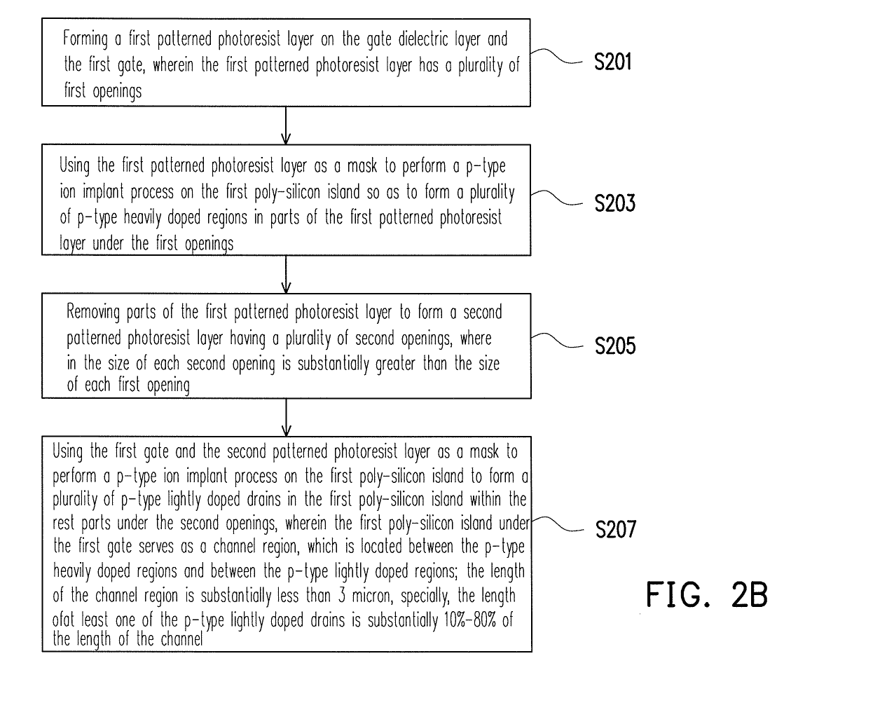

FIG. 2A is a locally sectional diagram of a semiconductor device according to an embodiment of the present invention. Referring to FIG. 2A, the method for fabricating a semiconductor device 200 in present embodiment includes forming a PMOS device 210 and an NMOS device 220 on a substrate 202, wherein the PMOS device 210 includes a first poly-silicon island 212, a gate dielectric layer 214 covering the first poly-silicon island 212, and a first gate 216 on the gate dielectric layer 214. As shown in FIG. 2A, the first gate 216 is located on the first poly-silicon island 212. The method of fabrication the PMOS device 210 is depicted as follows and shown in FIG. 2B.

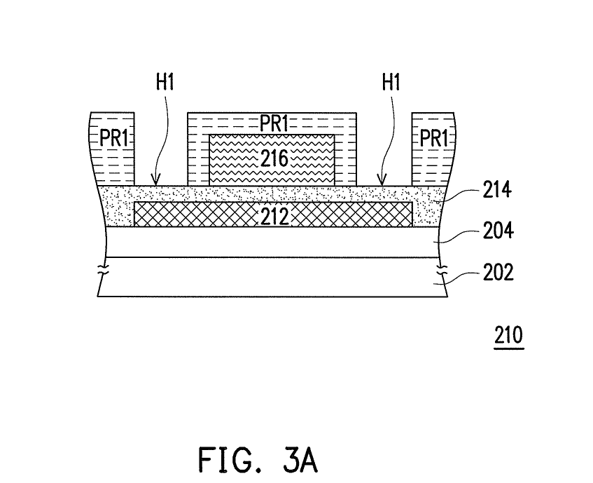

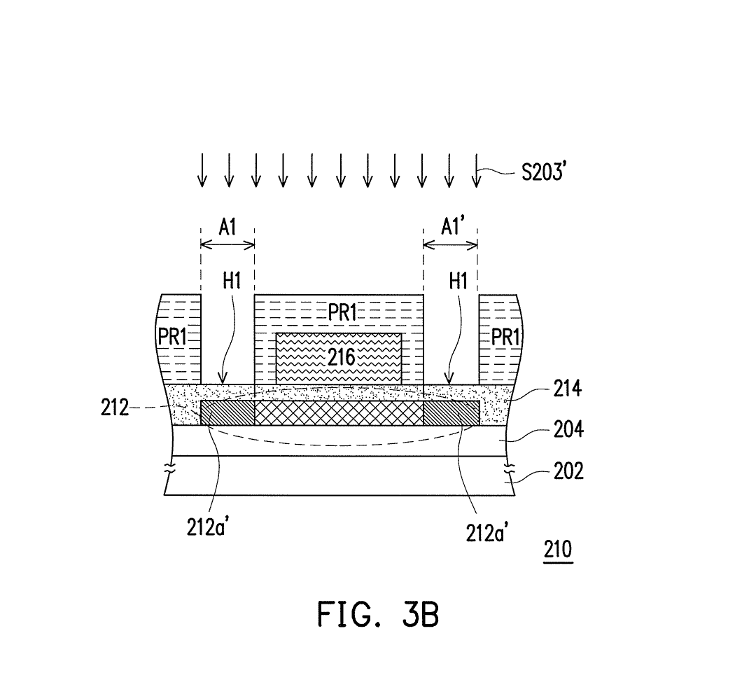

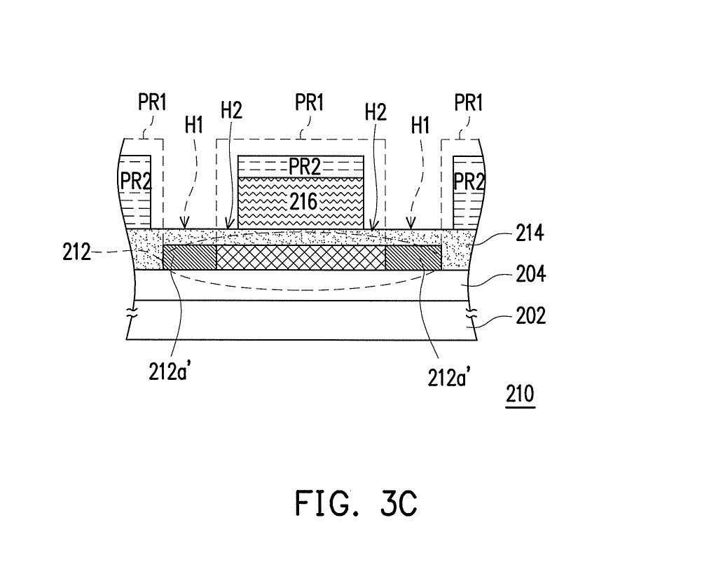

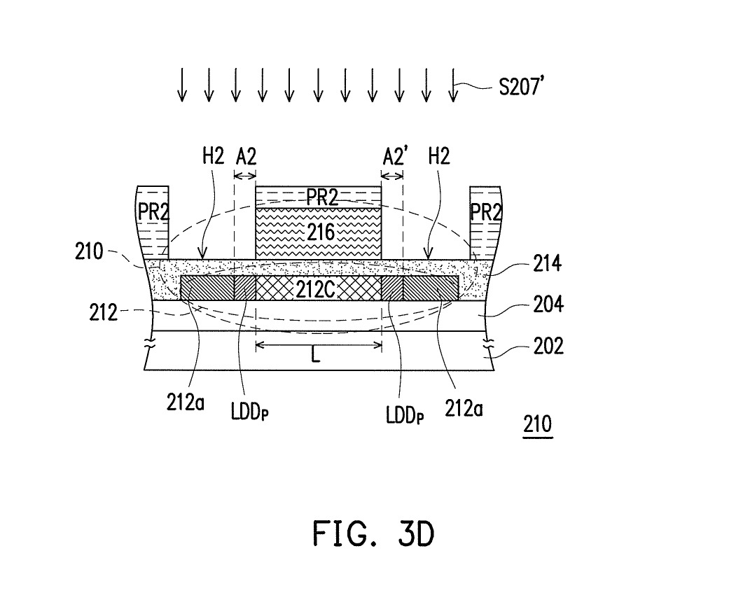

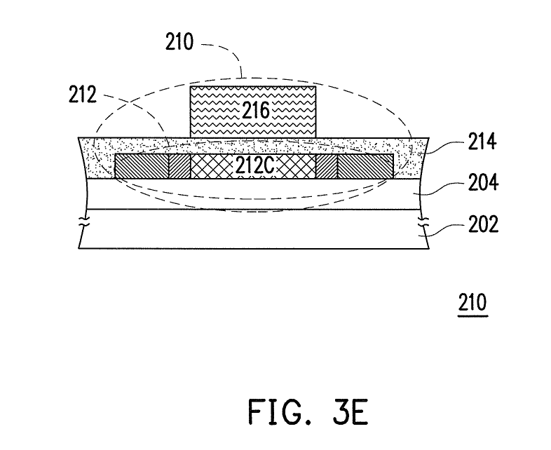

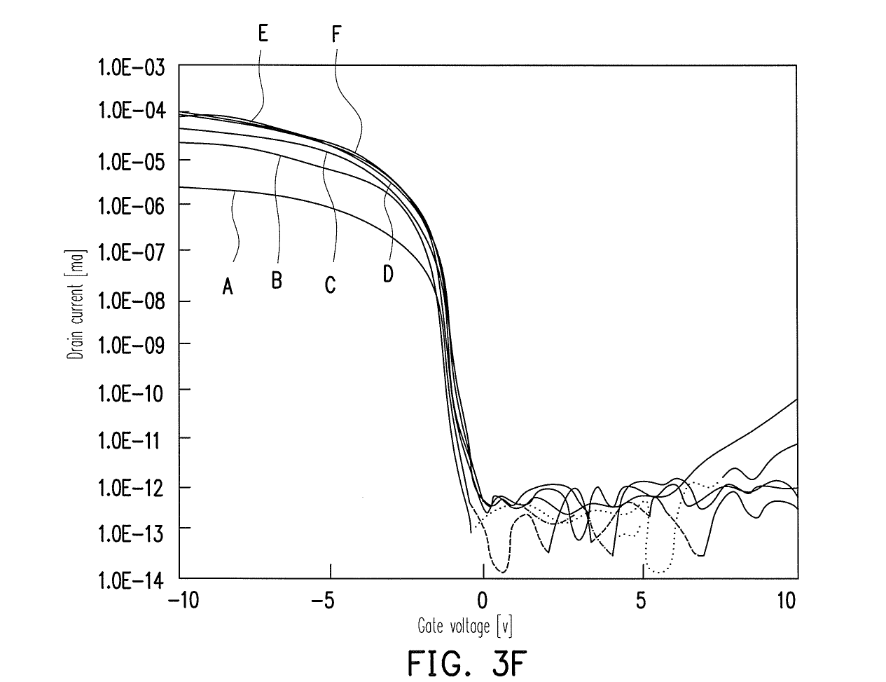

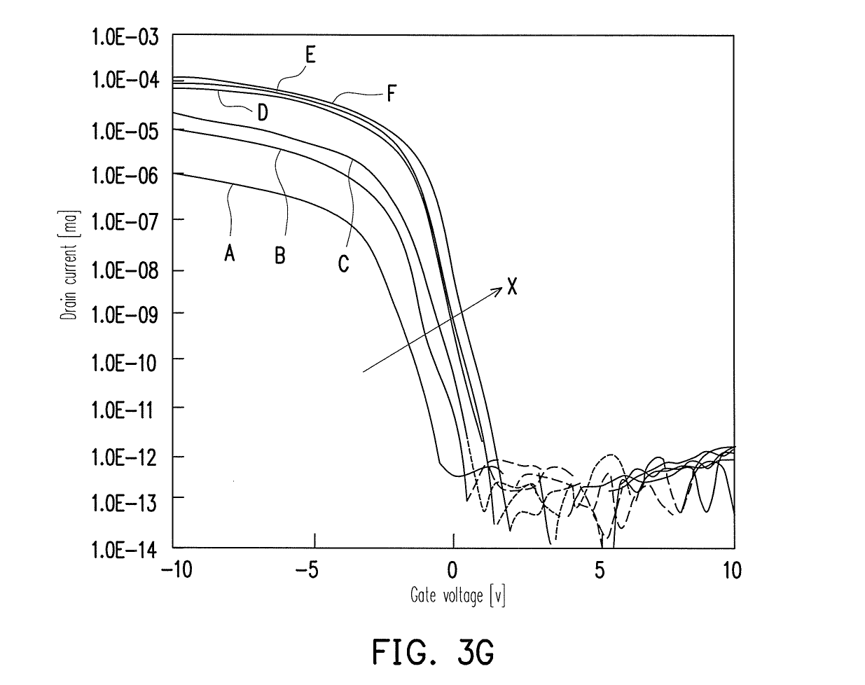

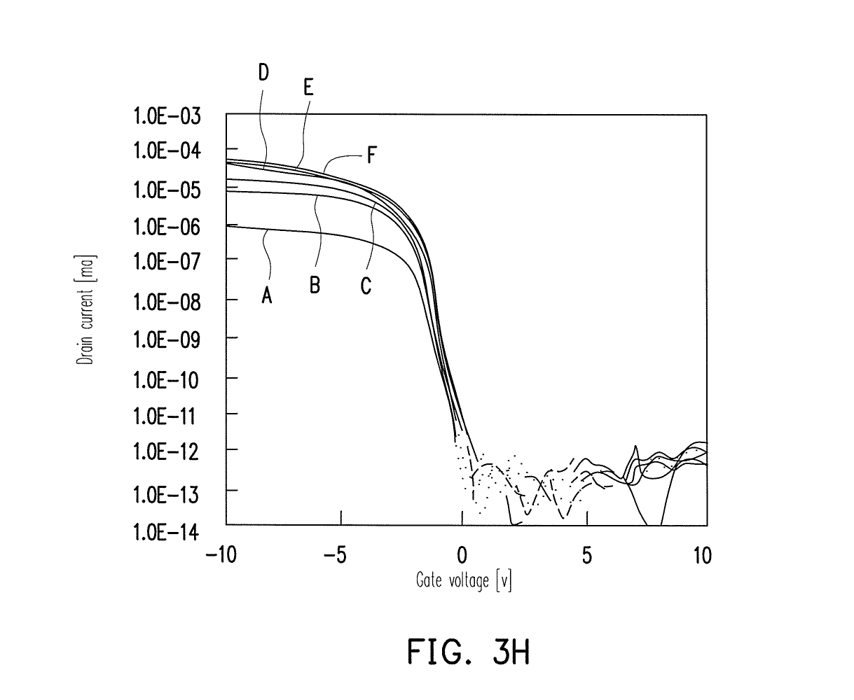

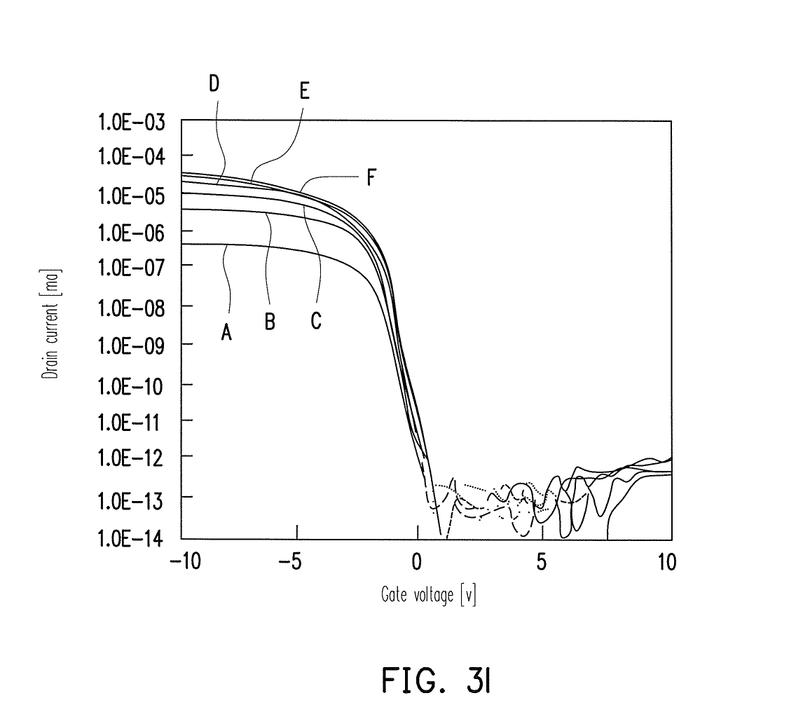

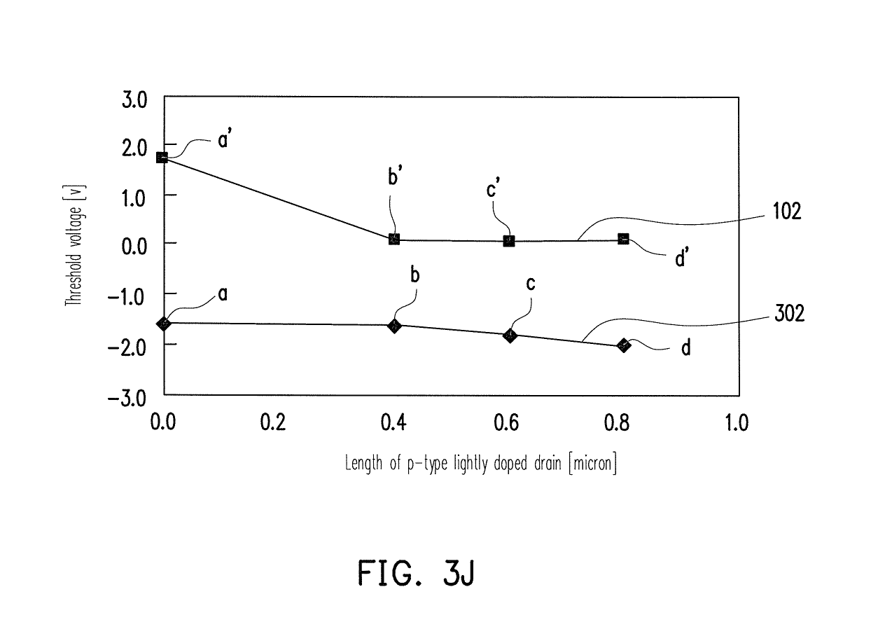

FIG. 2B is a flowchart of a method for fabricating a PMOS device according to an embodiment of the present invention and FIGS. 3A-3E are sectional diagrams of a PMOS device in association with a fabricating process flow according to an embodiment of the present invention. The method for fabricating the PMOS device 210 includes at least the following steps. Referring to FIGS. 2B and 3A, first in step S201, a first patterned photoresist layer PR1 is formed on the gate dielectric layer 214 and the first gate 216, wherein the first patterned photoresist layer PR1 has a plurality of first opening H1. In the embodiment, prior to forming the first patterned photoresist layer PR1, a buffer layer 204 can be optionally formed on the substrate 202, following by forming the first poly-silicon island 212 on the buffer layer 204.

The method of fabrication the first poly-silicon island 212 may include the following procedures. First, an a-Si layer is formed on the substrate 202 and the a-Si layer is annealed so as to transform the a-Si layer into a poly-silicon layer, wherein a method for annealing the a-Si layer is, for example, a laser annealing process. Then, the poly-silicon layer is patterned to form the first poly-silicon island 212, wherein the method for patterning the poly-silicon layer can be, but not limited to by the present invention, a photolithography and etching process (PEP). One skilled in the art can adopt other ways to form the first poly-silicon island 212 on the substrate 202. As an alternative solution however, a substrate 202 with a first poly-silicon island 212 can be obtained from directly purchasing, following by conducting the subsequent processes including, for example, ink-jet printing, screen printing, coating plus developing, deposition plus developing, or other appropriate processes to fabricate the first poly-silicon island 212.

Next, the gate dielectric layer 214, the first gate 216, and the first patterned photoresist layer PR1 are sequentially formed on the first poly-silicon island 212 as shown in FIG. 3A. In order to the form the first patterned photoresist layer PR1, for example, a photolithography and etching process (PEP) is used to form a first patterned photoresist layer PR1 with a plurality of first openings H1 on the substrate 202 so that the first patterned photoresist layer PR1 covers the first gate 216, the gate dielectric layer 214, and part of the first poly-silicon island 212. However, the present invention does not limit the above-mentioned method. In fact, the first patterned photoresist layer PR1 can be fabricated by using ink-jetting printing, screen printing, or other appropriate processes.

Then in step S203, referring to FIGS. 2B and 3B, a positive type ion (P-type ion) implant process S203′ is performed on the first poly-silicon island 212 by using the first patterned photoresist layer PR1 as a mask so as to form a plurality of P-type heavily doped regions 212a′ in parts of the first patterned photoresist layer 212 under the first contact holes H1. In more detail, the method of forming the P-type heavily doped regions 212a′ is, for example, to perform an ion implantation process so as to implant P-type ions in the first poly-silicon island 212 within the partial areas A1 and A1′ under the first openings H1.

Then in step S205, referring to FIGS. 2B and 3C, parts of the first patterned photoresist layer PR1 are removed to form a second patterned photoresist layer PR2 having a plurality of second openings H2, wherein the size of each second opening H2 is substantially greater than the size of each first opening H1. Referring to FIGS. 3B and 3C, the method of removing the parts of the first patterned photoresist layer PR1 is, for example, to perform an ashing process; i.e., to perform an anisotropic etching process on the first patterned photoresist layer PR1 to form the second patterned photoresist layer PR2, wherein the applicable gas plasma in the process is, for example, oxygen plasma, hydrogen plasma, helium plasma, other appropriate gas plasmas, or a combination of the above-mentioned plasmas.

Since the ashing process herein is an anisotropic etching process, therefore, the thickness of the first patterned photoresist layer PR1 gets thinner after the process to form the second patterned photoresist layer PR2 from the original first patterned photoresist layer PR1. Meanwhile, the first openings H1 get wider to form the second openings H2. In other words, the size of each second opening H2 is substantially greater than the size of each first opening H1, and the thickness of each second patterned photoresist layer PR2 is substantially less the thickness of each first patterned photoresist layer PR1.

In the embodiment, as shown in FIG. 3C, the edge of the second patterned photoresist layer PR2 is aligned with the edge of the first gate 216. In other embodiments however, the edge of the second patterned photoresist layer PR2 can be shrunk within the edge of the first gate 216. In other words, after the above-mentioned ashing process, the edge of the second patterned photoresist layer PR2 must be controlled without beyonding the edge of the first gate 216.

Then in step S207, as shown in FIGS. 2B and 3D, a P-type ion implant process S207′ is performed on the first poly-silicon island 212 by using the first gate 216 and the second patterned photoresist layer PR2 as a mask so as to form a plurality of P-type lightly doped drains LDD_{P} in the first poly-silicon island 212 within the rest parts A2 and A2′ under the second openings H2, wherein the P-type lightly doped drains LDD_{P} are also termed as P-type lightly doped regions LDD_{P}. In addition, the first poly-silicon island 212 under the first gate 216 serves as a channel region 212c, which is located between the P-type heavily doped regions (or namely HDD_{P}) 212a and between the P-type lightly doped regions LDD_{P}.

The length L of the channel region 212c is, for example, substantially less than 3 micron. When the length of the channel region 212c of the PMOS device 210 is substantially less than 3 micron, the problem caused by a short channel effect must be considered. In the embodiment, the PMOS device 210 employs P-type lightly doped drains LDD_{P} to reduce the short channel effect. Specially, the length of at least one of the P-type lightly doped drains LDD_{P} is substantially 10%-80% of the length of the channel region; preferably, the length of at least one of the P-type lightly doped drains LDD_{P} is substantially 20%-60% of the length of the channel region. In order to obtain evenly improved results contributed by each the P-type lightly doped drain LDD_{P}, the length of each the P-type lightly doped region LDD_{P} is preferably, but not limited to by the present invention, substantially equal to each other. In the other embodiments, the lengths of all the P-type lightly doped regions LDD_{P} may be not substantially equal to each other.

In the embodiment, a P-type ion implant process S207′ is performed on the first poly-silicon island 212 by using the first gate 216 and/or the second patterned photoresist layer PR2 on the first gate 216 as a mask so as to form the P-type lightly doped drains LDD_{P}. Once the P-type ion implant process S207′ is completed, the PMOS device 210 is almost completed.

The first poly-silicon island 212, the gate dielectric layer 214, and the first gate 216 together form the PMOS device 2 10 as shown in FIG. 3D, wherein the first poly-silicon island 212 includes a channel region 212c, P-type heavily doped regions 212a, and P-type lightly doped regions LDD_{P}. After removing the second patterned photoresist layer PR2 as shown in FIG. 3D, the PMOS device 210 is obtained as shown in FIG. 3E.

FIGS. 3F and 3G are curve graphs of drain current vs. gate voltage of a conventional PMOS device under different conditions, wherein the abscissa represents gate voltage (V_{G}) and the ordinate represents drain current (Id). In FIG. 3F, the length of the channel region in the conventional PMOS device is greater than or equal to 3 μm, the PMOS device does not contain a lightly doped region LDD, the gate voltage V_{G} ranges, for example, from −10V to 10V, and curves A, B, C, D, E and F respectively represent absolute values of operation voltage (|Vd|) of 0.1V, 1V, 2V, 4V, 6V, and 8V. It can be seen from the curves that the gate voltages (V_{G}) corresponding to the drain currents steeply dropping down are approaching 0V in convergence way, wherein the approached voltage corresponding to the drain currents steeply dropping down is termed as threshold voltage Vt and the threshold voltage Vt is measured by the gate voltage V_{G} corresponding to a standard drain current of 1E-9. In other words, the electric characteristic of the PMOS is not affected by the channel length and does not need a lightly doped region LDD.

In FIG. 3G, the length of the channel region in the conventional PMOS device is less than 3 μm (for example, 1.5 μm), the PMOS device does not contain a lightly doped region LDD, the gate voltage V_{G} ranges, for example, from −10V to 10V, and curves A, B, C, D, E and F respectively represent the absolute values of operation voltage (|Vd|) the same as that of FIG. 3F (0.1V, 1V, 2V, 4V, 6V, and 8V). It can be seen from the curves that the gate voltages (V_{G}) corresponding to the drain currents steeply dropping down are approaching in divergence way, wherein the approached voltage corresponding to the drain currents steeply dropping down is termed as threshold voltage Vt and the threshold voltage Vt is measured by the gate voltage V_{G} corresponding to a standard drain current of 1E-9. The electric characteristic of the PMOS in FIG. 3G is considerably different from that in FIG. 3F. That is, different operation voltages yield different threshold voltages Vt, and the threshold voltage Vt is increased with the operation voltage in an X direction (shown in FIG. 3G), which results in a severe offset with the electric characteristic of the semiconductor device due to the short channel effect.

FIGS. 3H and 3I are curve graphs of drain current (Id) vs. gate voltage (V_{G}) of a PMOS device under different operation voltages according to an embodiment of the present invention, wherein the abscissa represents gate voltage (V_{G}) and the ordinate represents drain current (Id). In FIGS. 3H and 3I, the length of the channel region in the PMOS device 210 ranges from 0 to 3 μm according to the present invention. In particular, the length of the channel region in FIGS. 3H and 3I is, for example but not limited by the present invention, 1.5 μm. The lengths of the P-type lightly doped drains LDD_{P} in the PMOS device are roughly, for example but not limited by the present invention, about 0.4 μm and about 0.8 μm. According to the present invention, the required length of at least one of the P-type lightly doped drains LDD_{P} is substantially 10%-80% of the length of the channel region 212c and preferably is substantially 20%-60% of that. In FIGS. 3H and 3I, the gate voltage V_{G} ranges, for example, from −10V to 10V, and curves A, B, C, D, E and F respectively represent absolute values of operation voltage (|Vd|) of 0.1V, 1V, 2V, 4V, 6V, and 8V (the same as in FIG. 3F). It can be seen from the curves in FIGS. 3H and 3I that the gate voltages (V_{G}) corresponding to the drain currents steeply dropping down are approaching a same gate voltage in convergence way, wherein the approached voltage corresponding to the drain currents steeply dropping down is termed as threshold voltage Vt and Vt is measured by the gate voltage V_{G} corresponding to a standard drain current of 1E-9. In contrast, the curves in FIG. 3G for a conventional PMOS device (the length of channel region is less than 3 μm and the PMOS device does not have P-type lightly doped drain), the corresponding threshold voltages Vt for different operation voltages are inconsistent in divergence way. In other words, the conventional PMOS device has a severe offset with the electric characteristic; but the PMOS device 210 of the present invention employing P-type lightly doped drains LDD_{P} can largely reduce the offset with the electric characteristic.

FIG. 3J is a diagram showing relationships between the threshold voltage Vt and the length of lightly doped region LDD respectively corresponding to a conventional PMOS device and an invented PMOS device provided by an embodiment of the present invention, wherein the lightly doped region LDD is also termed as P-type lightly doped drains LDD_{P}. The characteristic curve 102 indicates a divergence extent of the threshold voltages or the offsets of the PMOS 210 under different conditions; the characteristic curve 302 represents the measured threshold voltages of the PMOS 210 under different conditions. In more detail, the conditions corresponding to the points on the characteristic curve 102 are: the absolute values of operation voltage (|Vd|) are the same as the described above; the gate voltage V_{G} ranges, for example, from −10V to 10V; the threshold voltage is measured by the gate voltage V_{G} corresponding to a standard drain current of 1E-9. The points on the curve 102 are corresponding to the following conditions: the point a′ represents a conventional PMOS device, wherein the length of the channel region is less than 3 μm (for example, 1.5 μm), and the PMOS device does not contain a lightly doped region LDD; the point b′ represents a PMOS device of the present invention, wherein the length of the channel region is less than 3 μm (for example, 1.5 μm), and the PMOS device contains lightly doped regions LDD and the LDD length is substantially, for example, 0.4 μm; the point c′ represents a PMOS device of the present invention, wherein the length of the channel region is less than 3 μm (for example, 1.5 μm), and the PMOS device contains lightly doped regions LDD and the LDD length is substantially, for example, 0.6 μm; the point d′ represents a PMOS device of the present invention, wherein the length of the channel region is less than 3 μm (for example, 1.5 μm), and the PMOS device contains lightly doped regions LDD and the LDD length is substantially, for example, 0.8 μm. It can be seen that the PMOS device corresponding to the point a′ has a large threshold voltage offset; but the PMOS devices of the present invention corresponding to the points b′-d′ have a small threshold voltage approaching 0V, which indicates the threshold voltage offsets thereof are very small. The conditions of the characteristic curve 302 are the same as that of the curve 102. Although the threshold voltage values of the points on the characteristic curve 302 are slightly different, but in comparison with the threshold voltage offsets on the curve 102, it is obvious that the design of the present invention can effectively suppress the threshold voltage offsets, i.e. reduce the short channel effect to obtain stable electric characteristics. In addition, the above-mentioned channel lengths and the LDD lengths of the points in FIG. 3J are preferred examples, which the present invention is not limited to. The important requirements of the present invention are that the length of the channel region of the PMOS device is substantially less than 3 μm; the length of at least one of the P-type lightly doped drains LDD_{P} is substantially 10%-80% of the length of the channel region and preferably is substantially 20%-60% of the length of the channel region.

The semiconductor device 200 of the present invention comprises a PMOS device 210 and an NMOS device 220, wherein the method of fabrication the PMOS device 210 is described hereinbefore. The method of fabrication the NMOS device 220 is described as follows. There is no absolute sequence requirement to fabricate the PMOS device 210 and the NMOS device 220. That is., the PMOS 210 can be completed first, following by completing the NMOS device 220; or the NMOS 220 can be completed first, following by completing the PMOS device 210.

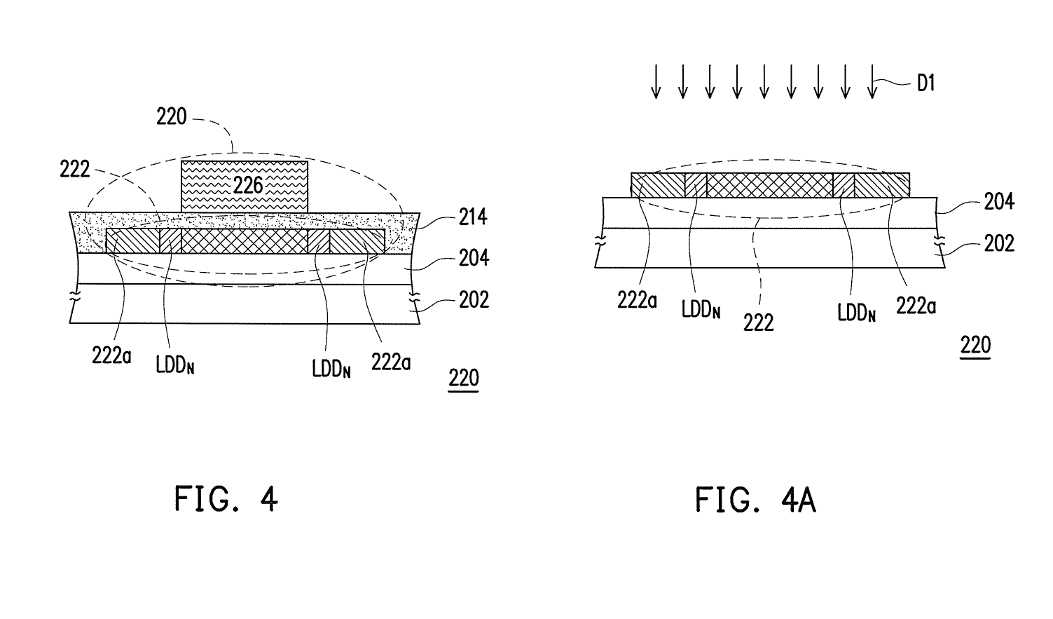

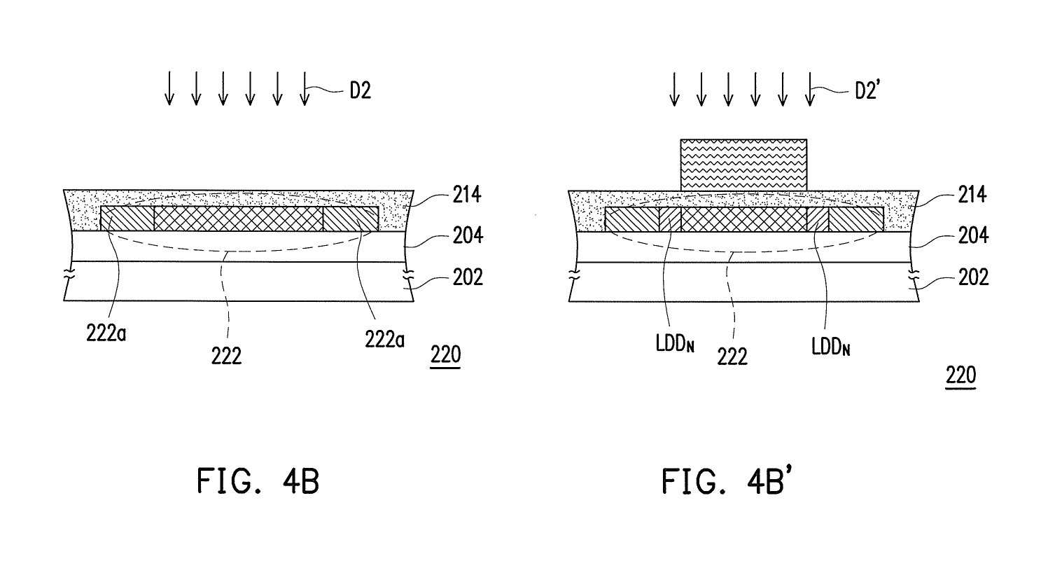

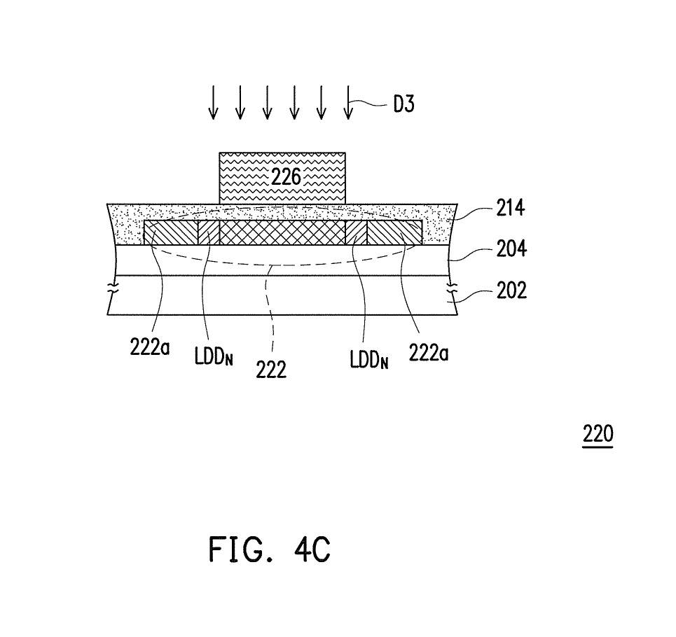

FIG. 4 is a locally sectional diagram of an NMOS device according to an embodiment of the present invention. Referring to FIG. 4, the NMOS device 220 of the embodiment includes a second poly-silicon island 222 and a second gate 226 on the gate dielectric layer 214, wherein the second gate 226 is located over the second poly-silicon island 222. The method of fabrication the NMOS device 220 includes performing a negative type ion (N-type ion) implant process on parts of the second poly-silicon island 222 to form a plurality of N-doped regions 222a and LDD_{N}. In the embodiment, the N-doped regions 222a are, for example, N-type heavily doped regions and the N-doped regions LDD_{N} are, for example, N-type lightly-doped regions.

Note that the present invention does not limit the steps of forming the N-doped regions 222a and LDD_{N}. FIG. 4A is a locally sectional diagram of an N-doped region according to an embodiment of the present invention, FIG. 4B and FIG. 4B′ are two locally sectional diagrams of an N-doped region according to another embodiment of the present invention and FIG. 4C is a locally sectional diagram of an N-doped region according to yet another embodiment of the present invention. Referring to FIG. 4A, in the embodiment, after the second poly-silicon island 222 is fabricated completely, a plurality of N-type ion implant processes DI with different dosages are performed on different parts of the second poly-silicon island 222 to form N-doped regions 222a and LDD_{N}.

In another embodiment, the N-doped regions 222 and LDD_{N} are fabricated respectively similarly to the method of fabrication P-type heavily doped regions 212a and P-type lightly doped regions LDD_{P} for process convenience. First referring to FIG. 4B, a gate dielectric layer 214 over the second poly-silicon island 222 is fabricated. Next, an N-type ion implant process D2 is performed on parts of the second poly-silicon island 222 to form N-doped regions. Then referring to FIG. 4B′, a second gate 226 over the gate dielectric layer 214 is fabricated. After that, an N-type ion implant process D2′ is performed on parts of the second poly-silicon island 222 to form the N-doped regions LDD_{N}.

Referring to FIG. 4C, in another embodiment, after the second gate 226 is formed over the gate dielectric layer 214, a plurality of N-type ion implant processes D3 with different dosages are performed on different parts of the second poly-silicon island 222 to form N-doped regions 222a and LDD_{N}.

Note that there is no strict sequence requirement to fabricate the above-mentioned N-doped regions 222a and LDD_{N}. Moreover, there is no strict sequence requirement to fabricate the above-mentioned N-doped regions 222a, gate dielectric layer 214, and second gate 226; even there is no strict sequence requirement to fabricate the above-mentioned N-doped regions LDD_{N}, gate dielectric layer 214, and second gate 226. In other words, the present invention does not limit the fabrication method of the N-doped regions 222a and LDD_{N}, wherein a channel region (not shown) is disposed between the N-doped regions 222a and LDD_{N} and the channel region is substantially less than 3 micron.

Referring to FIGS. 4, 4A, 4B, and 4B′ or 4C, the N-doped regions 222a and LDD_{N} can be fabricated in various ways. For example, the N-doped regions 222a and LDD_{N} can be defined and fabricated by performing two photolithography and etching processes, or by performing a photolithography and etching process (PEP) in association with other processes (for example, an ashing process) or by performing any other suitable processes. In short, the present invention does not limit the fabrication method and the steps of the NMOS device 220 of the present invention.

After forming the PMOS device 210 and the NMOS device 220, the other steps for fabricating the semiconductor device 200 are sequentially conducted. FIGS. 3A-3E, 4, 4A, 4B, 4B′, 4C and 5A-5E are sectional diagrams of a semiconductor device according to an embodiment of the present invention, wherein FIGS. 3A-3E are corresponding to the fabrication of the PMOS device 210, and FIGS. 4, 4A, 4B, 4B′, 4C and 5A-5E are corresponding to the fabrication of the NMOS device 220. As described above, the present invention does not limit the fabricating sequence for the PMOS device 210 and the NMOS device 220.

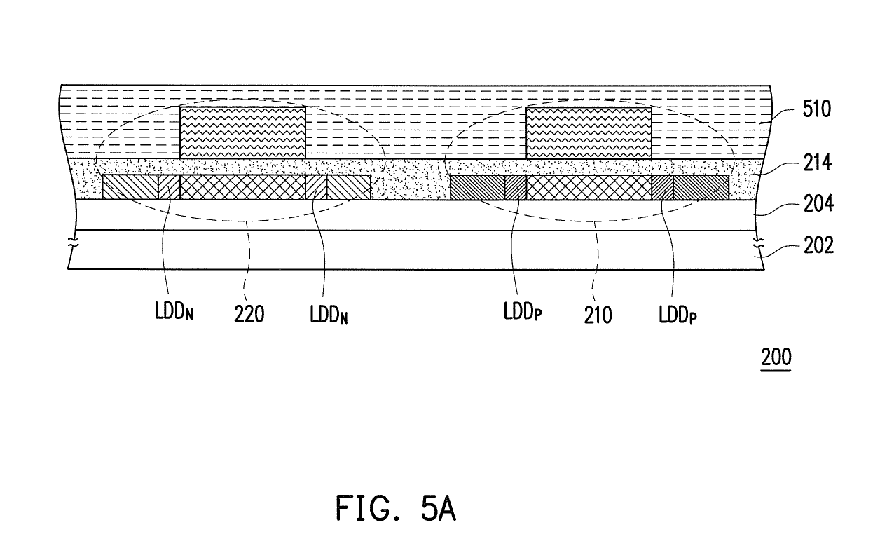

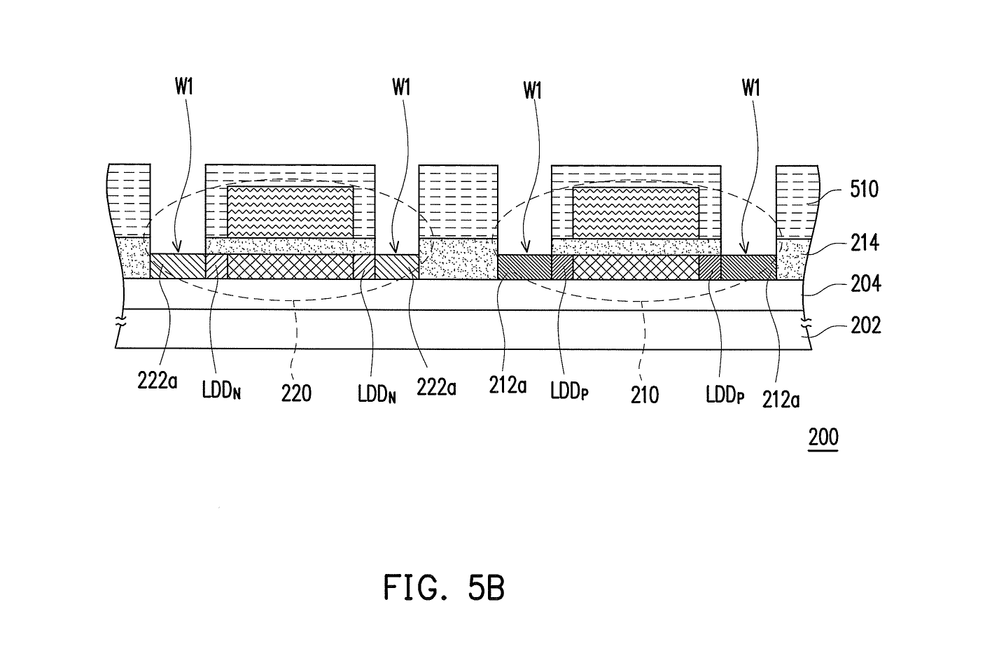

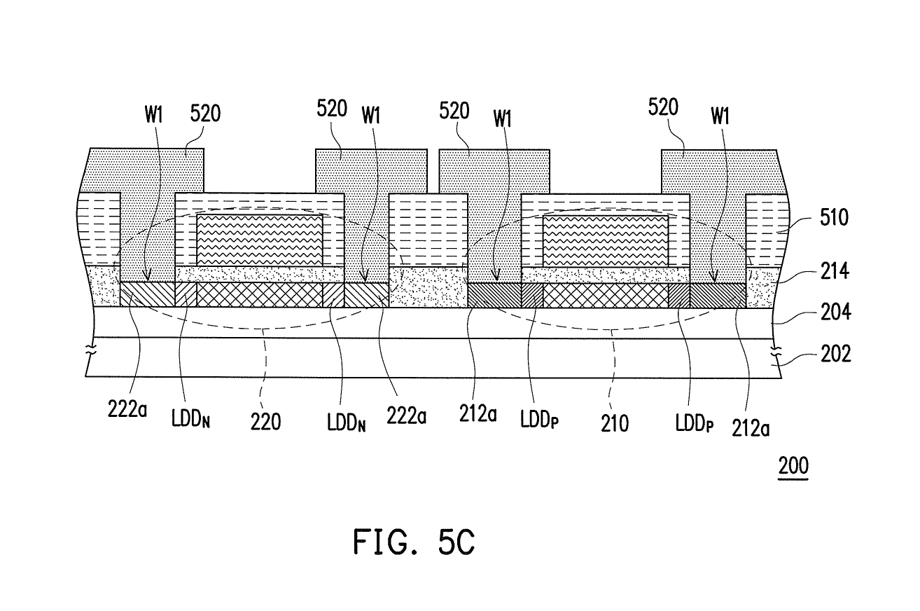

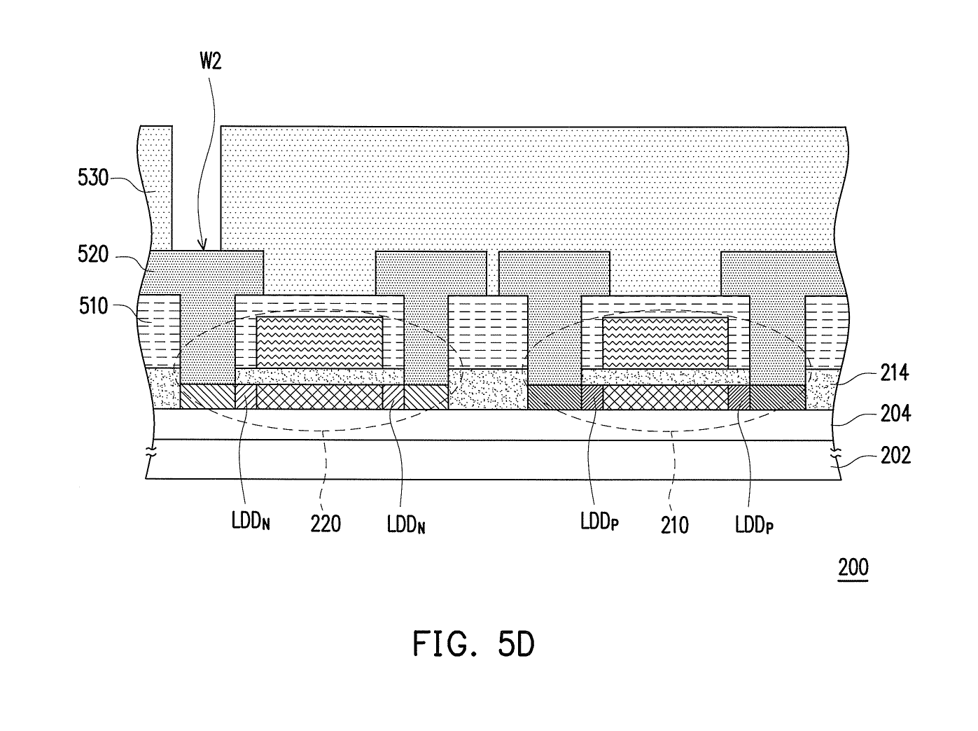

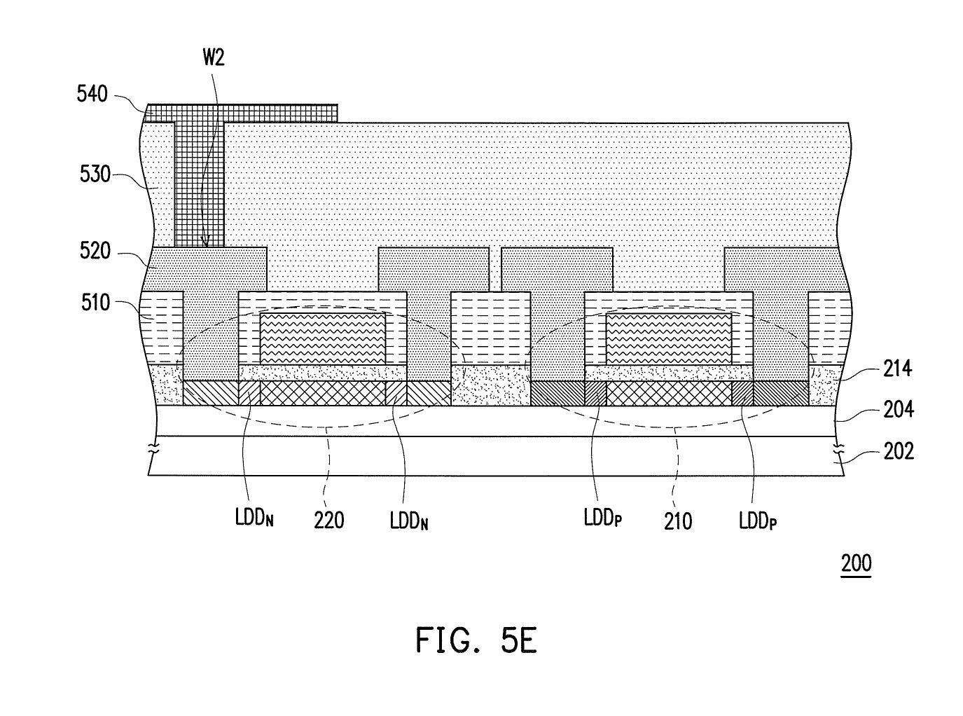

After completing the PMOS device 210 and the NMOS device 220, the subsequent fabrication steps are shown in FIG. 5A. First, an interlayer dielectric 510 is formed on the first gate 216, the second gate 226 and the gate dielectric layer 214; i.e., the ILD 510 is formed over the PMOS device 210 and the NMOS device 220. The PMOS device 210 herein has P-type lightly doped drains LDD_{P} and the NMOS device 220 has N-type lightly doped drains LDD_{N}.

Then referring to FIG. 5B, the interlayer dielectric 510 and the gate dielectric layer 214 are patterned to form a plurality of first contact holes W1 corresponding to the N-doped regions 222a and the P-type heavily doped regions 212a in the interlayer dielectric 510 and the gate dielectric layer 214, wherein the N-doped regions 222a corresponding to the first contact holes W1 are, for example, N-type heavily doped regions.

Then referring to FIG. 5C, a plurality of conductors 520 is formed in the first contact holes W1, wherein the conductors 520 are electrically connected to the N-doped regions 222a and the P-type heavily doped regions 212a.

Then referring to FIG. 5D, a patterned passivation layer 530 is optionally formed on the interlayer dielectric 510 and the conductor 520, wherein the patterned passivation layer 530 has a plurality of second contact holes W2 therein (in FIG. 5D, for example, only one second contact hole is shown).

Then referring to FIG. 5E, a conductive layer 540 is formed on the patterned passivation layer 530, and the conductive layer 540 is electrically connected to the partial conductors 520 via the second contact holes W2; i.e., the conductive layer 540 is formed on the interlayer dielectric 510 and the partial conductors 520, so that the conductive layer 540 is electrically connected to the partial conductors 520. At the time, the semiconductor device 200 is nearly completed.

Note that the condition for the NMOS device 220 to have the N-doped regions LDD_{N} can be different from the condition for the PMOS device 210 to have the P-doped regions LDD_{P}; but it is preferred to make the condition for the NMOS device 220 to have the N-doped regions LDD_{N} is the same as the condition for the PMOS device 210 to have the P-doped regions LDD_{P} in the present invention.

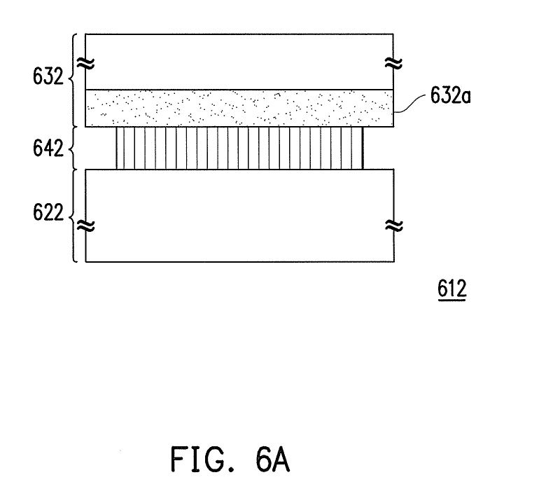

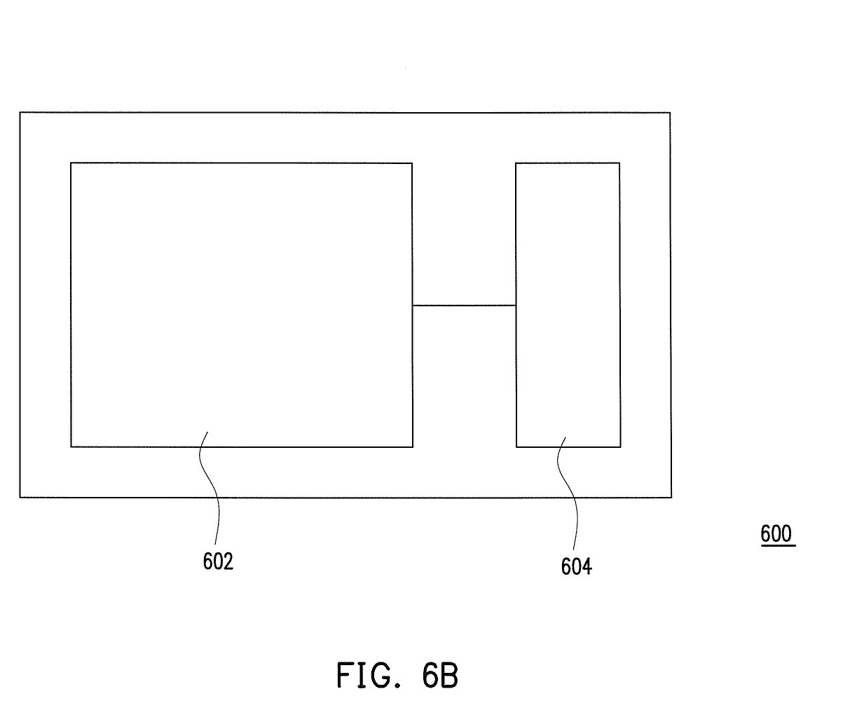

The structure of the semiconductor device 200 and the fabrication method thereof can be used in display apparatuses and the fabrication method thereof, wherein the semiconductor device 200 is applicable in at least one of the pixel region (not shown), the peripheral driving circuit region (not shown), and other external components (not shown). The semiconductor device 200 is, preferably but not limited to by the present invention, used in the pixel region of a display apparatus. When the semiconductor device 200 is used in the pixel region of a display apparatus, the conductive layer 540 can be called as a pixel electrode, wherein the architecture of the corresponding display apparatus is shown in FIG. 6A. FIG. 6A is a diagram of a display apparatus according to an embodiment of the present invention. Referring to FIG. 6A, a display apparatus 602 of the embodiment includes at least a display panel 612, which includes at least a pixel array substrate 622, another substrate 632 parallel to the pixel array substrate 622 and a display medium 642 disposed between the pixel array substrate 622 and the substrate 632, wherein the pixel array substrate 622 has the above-mentioned semiconductor devices 200, and the other substrate 632 has an optional transparent electrode 632a. When the display medium 642 is liquid crystal material, the display apparatus 602 is called as liquid crystal display panel (LCD panel), such as transmissive display panel, transfective display panel, reflective display panel, color filter on array display panel (COA display panel), array on color filter display panel (AOC display panel), vertical alignment display panel (VA display panel), in-plane switching display panel (IPS display panel), multi-domain vertically alignment display panel (MVA display panel), twisted nematic display panel (TN display panel), super twisted nematic (STN display panel), patterned vertical alignment display panel (PVA display panel), super patterned vertical alignment display panel (S-PVA display panel), advanced super view display panel (ASV display panel), fringe field switching display panel (FFS display panel), continuous pinwheel alignment display panel (CPA display panel), axially symmetric aligned microcell display panel (ASM display panel), optically compensated bend display panel (OCB display panel), super in-plane switching display panel (S-IPS display panel), advanced super in-plane switching display panel (AS-IPS display panel), ultra fringe field switching display panel (UFFS display panel), anisotropic polymer-dispersed display panel, dual-view display panel, triple-view display panel, three-dimensional display panel (3-D display panel), display panel in other modes or a combination of the above-mentioned modes. The LCD panel belongs to a non-self-luminescent. If the display medium 642 is an electroluminescent material (EL material), the display apparatus 602 is called as electroluminescent display (ELD), such as phosphoresce ELD panel, fluorescent phosphoresce ELD panel or a combination of the above-mentioned modes. The display apparatus 602 belongs to a self-luminescent display panel, wherein the EL material can be organic material, inorganic material or a combination of the above-mentioned materials. In terms of the molecule size of the above-mentioned materials, it can be small molecule, macromolecule or a combination of them. If the display medium 642 contains both liquid crystal material and EL material, the display apparatus 602 is termed as hybrid display or semi self-luminescent display.

The structure of the semiconductor device 200 and the fabrication method thereof can be used also in photo-electrical apparatus and the fabrication method thereof, wherein the architecture of the photo-electrical apparatus is shown in FIG. 6B. FIG. 6B is a diagram of a photo-electrical apparatus according to an embodiment of the present invention. Referring to FIG. 6B, a photo-electrical apparatus 600 of the embodiment includes a display apparatus 602 and an electronic component 604 electrically connected to the display apparatus 602. The electronic component 604 of the embodiment includes, for example, control component, operation component, processing component, input component, memory device, driving device, light-emitting device, protection component, sensing component, detection component, components with other functions, or a combination of the above-mentioned components/devices. The photo-electrical apparatus 600 of the embodiment includes portable electronic products, such as handset, video camera, camera, laptop, game machine, watch, music player, electronic mail transceiver, global positioning system (GPS), digital picture or similar electronic products. The photo-electrical apparatus 600 of the embodiment also includes audio/video products (AV products) (for example, AV player or similar products), screen, television set, display board and panel in a projector.

The fabrication method of the semiconductor device provided by the present invention can be used to fabricate a semiconductor device composed of PMOS devices and NMOS devices, wherein both the PMOS device and the NMOS device have lightly doped drains so as to improve the short channel effects in the PMOS device and the NMOS device.

Besides, the present invention is capable of fabricating the self-aligned lightly doped drains in the PMOS device without performing additional photomask alignment processes, and therefore, the present invention can avoid a possible mis-alignment during fabricating the lightly doped drains. In short, the method of fabrication the semiconductor device in the present invention is advantageous in not only higher production yield, but also saving the cost to fabricate the photomask.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for fabricating a semiconductor device, comprising:
forming a P-type metal oxide semiconductor device and an N-type metal oxide semiconductor device on a substrate, wherein the P-type metal oxide semiconductor device comprises a first poly-silicon island, a gate dielectric layer covering the first poly-silicon island and a first gate located on the gate dielectric layer, and the method of fabrication the P-type metal oxide semiconductor device comprises:
forming a first patterned photoresist layer on the gate dielectric layer and the first gate, wherein the first patterned photoresist layer has a plurality of first openings;
performing a P-type ion implant process on the first poly-silicon island by using the first patterned photoresist layer as a mask to form a plurality of P-type heavily doped regions in the first poly-silicon island under the first openings;
removing parts of the first patterned photoresist layer to form a second patterned photoresist layer having a plurality of second openings, wherein a size of each second opening is substantially greater than a size of each first opening; and
performing a P-type ion implant process on the first poly-silicon island by using the first gate and the second patterned photoresist layer as a mask to form a plurality of P-type lightly doped regions in the first poly-silicon island under the second openings, wherein the part of the first poly-silicon island under the first gate serves as a channel region located between the P-type heavily doped regions and between the P-type lightly doped regions, a length of the channel region is substantially less than 3 micron, and a length of at least one of the P-type lightly doped regions substantially is 10%-80% of the length of the channel region.

2. The method for fabricating a semiconductor device according to claim 1, wherein the method of fabrication the first poly-silicon island comprises:
forming an amorphous silicon layer on the substrate;
annealing the amorphous silicon layer to transform the amorphous silicon layer into a poly-silicon layer; and
patterning the poly-silicon layer to form the first poly-silicon island.

3. The method for fabricating a semiconductor device according to claim 2, wherein the method for annealing the amorphous silicon layer comprises a laser annealing process.

4. The method for fabricating a semiconductor device according to claim 1, wherein the method for removing parts of the first patterned photoresist layer comprises an ashing process.

5. The method for fabricating a semiconductor device according to claim 1, further comprising removing the second patterned photoresist layer.

6. The method for fabricating a semiconductor device according to claim 1, wherein the N-type metal oxide semiconductor device comprises a second poly-silicon island and a second gate on the gate dielectric layer, the second gate is located on the second poly-silicon island, and a method for fabricating the N-type metal oxide semiconductor device comprises performing an N-type ion implant process on the second poly-silicon island to form a plurality of N-doped regions.

7. The method for fabricating a semiconductor device according to claim 6, wherein the N-doped regions comprise a plurality of N-type lightly-doped regions and a plurality of N-type heavily doped regions.

8. The method for fabricating a semiconductor device according to claim 6, further comprising:
forming an interlayer dielectric on the first gate, the second gate, and the gate dielectric layer;
patterning the interlayer dielectric and the gate dielectric layer to form a plurality of first contact holes corresponding to the N-doped regions and the P-type heavily doped regions in the interlayer dielectric and the gate dielectric layer; and
forming a plurality of conductors electrically connected to the N-doped regions and the P-type heavily doped regions in the first contact holes.

9. The method for fabricating a semiconductor device according to claim 8, further comprising:
forming a patterned passivation layer on the interlayer dielectric and the conductors, wherein the patterned passivation layer has a plurality of second contact holes; and
forming a conductive layer on the patterned passivation layer so that the conductive layer is electrically connected to parts of the conductors via the second contact holes.

10. The method for fabricating a semiconductor device according to claim 8, further comprising:
forming a conductive layer on the interlayer dielectric and parts of the conductors so that the conductive layer is electrically connected to the parts of the conductors.

11. A method of fabrication a display apparatus, comprising the method according to claim 1.

12. A method of fabrication a photo-eletrical apparatus, comprising the fabrication method according to claim 1.

13. A semiconductor device, comprising:
a substrate;
at least a P-type metal oxide semiconductor device disposed on the substrate, wherein the P-type metal oxide semiconductor device comprises a first poly-silicon island, a gate dielectric layer covering the first poly-silicon island, and a first gate located on the gate dielectric layer, the first gate is located on the first poly-silicon island, the first poly-silicon island has a plurality of P-type heavily doped regions, a plurality of P-type lightly doped regions, and a channel region between the P-type lightly doped regions in the first poly-silicon island, a length of the channel region is substantially less than 3 micron and a length of at least one of the P-type lightly doped regions substantially is 10%-80% of the length of the channel region; and
at least an N-type metal oxide semiconductor device disposed on the substrate, wherein the N-type metal oxide semiconductor device comprises a second poly-silicon island, a gate dielectric layer covering the second poly-silicon island, and a second gate on the gate dielectric layer, the second gate is located on the second poly-silicon island, the second poly-silicon island has a plurality of N-type heavily doped regions, a plurality of N-type lightly-doped regions, and a channel region between the N-type lightly-doped regions in the second poly-silicon island.

14. The semiconductor device according to claim 13, further comprising:
an interlayer dielectric disposed on the first gate, the second gate, and the gate dielectric layer, wherein the interlayer dielectric and the gate dielectric layer have a plurality of first contact holes corresponding to the N-doped regions and the P-type heavily doped regions in the interlayer dielectric and the gate dielectric layer; and
a plurality of conductors electrically connected to the N-doped regions and the P-type heavily doped regions in the first contact holes.

15. The semiconductor device according to claim 13, further comprising:
a patterned passivation layer disposed on the interlayer dielectric and the conductors, wherein the patterned passivation layer has a plurality of second contact holes in the patterned passivation layer; and
a conductive layer disposed on the patterned passivation layer so that the conductive layer is electrically connected to parts of the conductors via the second contact holes.

16. The semiconductor device according to claim 13, further comprising:
a conductive layer disposed on the interlayer dielectric and parts of the conductors so that the conductive layer is electrically connected to the parts of the conductors.

17. A display apparatus, comprising the semiconductor device according to claim 13.

18. A photo-electrical apparatus, comprising the semiconductor device according to claim 17.
